(19) United States
(12) Patent Application Publication
(10) Pub. No.: US 2015/0083220 A1
(43) Pub. Date: Mar. 26, 2015

(54) FIELD-ASSEMBLABLE CONCENTRATION PHOTOVOLTAICS SYSTEM

(71) Applicant: Ricard Pardell Vilella, Valldoreix (ES)

(72) Inventor: Ricard Pardell Vilella, Valldoreix (ES)

(21) Appl. No.: 14/394,344

(22) PCT Filed: Apr. 18, 2013
(86) PCT No.: PCT/EP2013/058049

§ 371 Date: Oct. 14, 2014

Related U.S. Application Data
(60) Provisional application No. 61/625,693, filed on Apr. 18, 2012.

(51) Int. Cl. H02S 30/10; H01L 31/054

(52) U.S. Cl. CPC H02S 30/10; H01L 31/0543
USPC 136/259; 29/592.1

(57) ABSTRACT

A concentration photovoltaic CPV assembly system is provided that allows on-field assembly, space-efficient storage and optimized shipment. The CPV assembly system is configured to be stored and transported in an un-assembled state, and configured to be mounted on site while safeguarding the tight mounting tolerances and environmental protection requirements, as well as all the geometrical requirements of the optical system.

### TECHNICAL FIELD

The present invention relates generally to the assembly of concentration photovoltaic CPV systems, and in particular to a CPV assembly system that facilitates pre-assembly storage and transport as well as allows field-assembly of the CPV system.

### BACKGROUND OF THE INVENTION

Concentration photovoltaic CPV technology uses optics such as lenses or curved mirrors to concentrate a large amount of sunlight onto a small area of solar photovoltaic PV cells to generate electricity. CPV systems usually comprise a plurality of primary optical elements POE that concentrate incoming light onto a plurality of CPV receivers. One common kind of CPV systems is based on the combination of primary refractive optics with CPV receivers arranged in a matrix pattern.

The optics and receivers must be protected from the environment and therefore the ensemble constitutes a shape similar to a box, its depth being basically determined by the primary optics focal length and its width and length determined by each primary optics dimensions and by the number of receivers arranged in each dimension. Therefore the assembly of such systems requires high technological installation sites to guarantee the tight tolerance requirements of CPV systems.

The volume filled by a refractive CPV module is therefore proportional to the primary optics focal length. Given a specific concentration ratio (solar aperture to cell area ratio) and a primary optics F number (focal length to aperture ratio), the focal length and therefore the depth of the module is proportional to the cell size, and so the volume of the module. As a consequence, the volume of CPV modules is a function of cell size, concentration ratio and primary optics F number. The volume of CPV systems having medium to large CPV cells (4 mm side or more) is therefore significantly large.

This significant volume poses a logistic problem. Storing and transporting through long distances large volumes of air is not efficient. The larger the cells the larger this problem becomes, reducing CPV advantages in front of flat photovoltaic PV panels. Some CPV manufacturers have decided to use very small CPV cells (in the order of 1 mm side) in order to alleviate this problem. This can increase the cost due to the multiplication of CPV receivers per power unit it implies.

Therefore a need has been identified to provide a CPV system that combines larger cells in such a way that it is possible to ship the components to a low technology installation site and to assemble them on field, while avoiding the logistics problem associated with the transport of CPV cells. In order to fulfill this need, the tight mounting tolerances and environmental protection requirements of CPV systems have to be obeyed. Also, the modules have to allow an assembly process that respects all the geometrical requirements of the optical system.

### SUMMARY

It is therefore an object of the present invention to provide solutions to the above mentioned problems. In accordance with one or more embodiments and corresponding disclosure thereof, various aspects are described in connection with providing a CPV assembly system that allows on-field assembly, space-efficient storage and optimized shipment, all in a repetitive manner.

In a preferred embodiment of the invention a concentration photovoltaic CPV assembly system is provided which occupies little space during storage and facilitates its transport due to the flat structure of its components as well as facilitates field assembly into a rigid structure with tight mounting tolerances.

### BRIEF DESCRIPTION OF THE DRAWING(S)

The features and advantages of the present invention become more apparent from the detailed description set forth below when taken in conjunction with the drawings in which like reference characters identify corresponding elements in the different drawings. Corresponding elements may also be referenced using different characters.

FIG. 1 is a general overview of the assembled CPV assembly system of the invention.

FIG. 2 is an exploded view of the CPV assembly system of the invention.

FIG. 3 is a detailed view of mounting brackets fixing means on the optics panel of the CPV assembly system of the invention.

FIG. 4 is a diagonal view of the frame section of the CPV assembly system of the invention.

FIG. 5 is a cross-sectional view of one corner of the assembled CPV assembly system of the invention.

### DETAILED DESCRIPTION OF THE INVENTION

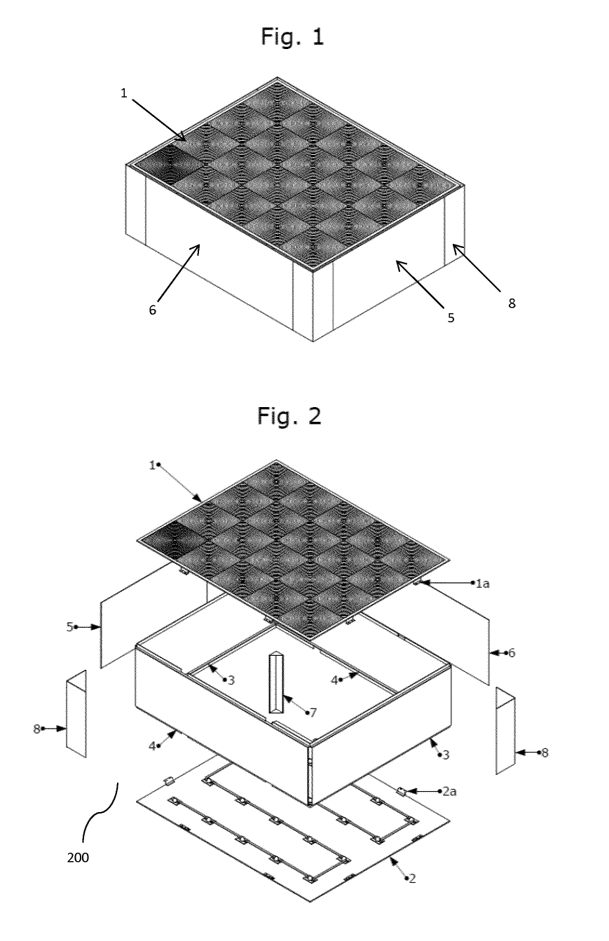

FIG. 1 is a general overview of an assembled CPV assembly system according to one embodiment of the present invention. It should be noted that in its mounted state the CPV assembly system comprises mostly air thereby posing a transport problem if transported to the installation site as a ready-made assembled system.

FIG. 2 is an exploded view of the CPV assembly system 200. The CPV assembly system 200 comprises a upper primary optical section 1 (primary optics panel), an lower photovoltaic receiving section 2 (receiver panel), a frame section 9 (side walls), and fixing means for assembling the upper, lower and frame sections together enabling sun light to be concentrated by the upper primary optical section in between the frame section onto the lower photovoltaic receiving section. These plurality of sections are substantially flat enabling minimizing the space occupied when un-assembled and the CPV system transport.

As can be seen the upper primary optical section comprises at least one primary refractive optic, the lower photovoltaic receiving section comprises at least one CPV receiver, and the upper and lower sections are parallel with respect to each other. The frame section 9 comprises an internal section and an external section. The internal section comprises four opposing internal walls. The external section comprises four opposing external walls. Once the internal and external walls are assembled together they form a frame on which the upper and lower sections can subsequently be mounted.

In other words, the CPV assembly system 200 comprises a primary optics panel including a plurality of mounting brackets 1a, a receiver panel including mounting brackets 2a, short and long internal walls 3 and 4, short and long external walls 5 and 6, internal corners 7 and external corners 8. It should be noted, that the components comprised by the CPV assembly system 200 are basically flat, and can therefore be packed and shipped efficiently as a kit, in order to assemble them near the installation site requiring facilities and tools requiring a minimal capital investment.

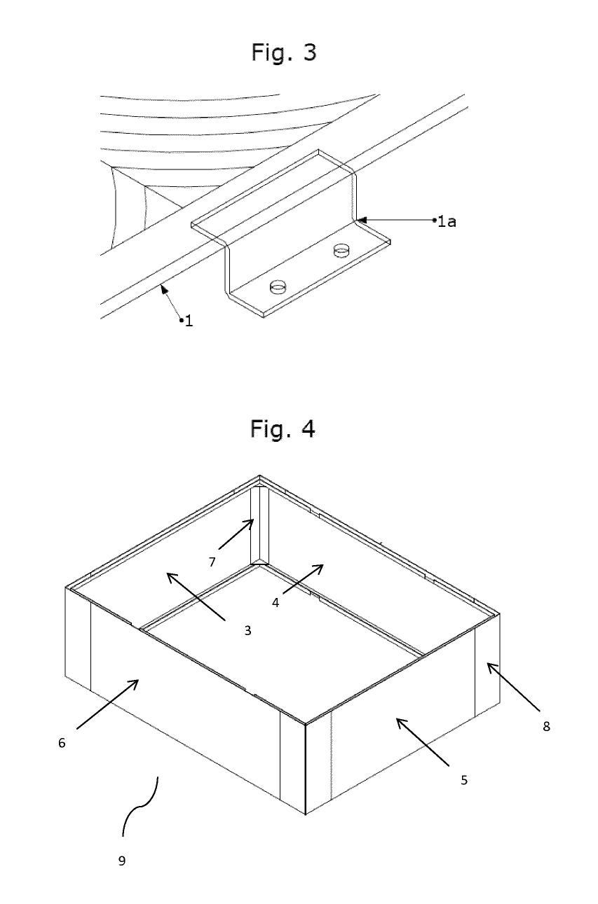

FIG. 3 is a detailed view of the assembly of the mounting brackets on the optics panel comprised in the CPV assembly system. Brackets 1a and 2a (not shown), including mounting holes, are glued to glass or plastic primary optics panel 1 using a very tight tolerance positioning method. In a preferred embodiment of the invention, these brackets are made of stainless steel or a similar material and are glued using pressure sensitive or UV curing acrylic adhesive.

FIG. 4 is an upper view of the CPV assembly system of the present invention showing the frame section 9 comprising the assembled internal and external frame walls. It should be noted that the structural members and walls are riveted together using premade holes, thereby obtaining a module assembly frame. The formation of this frame provides structural stability to the CPV assembly system. Subsequently, primary optics panels 1 and receiver panels 2 are fastened to this frame by means of mounting brackets 1a and 2a.

Consequently, if the components have been manufactured using high tech machinery and obey the most strict quality assurance procedures the CPV assembly system provides a reference system in order to mount the CPV assembly system on, or close to, the installation site whilst respecting all the geometrical requirements of the optical system, thereby allowing a correct operation of the module.

In a preferred embodiment of the invention, frame section 9 is painted with epoxy powder using an electrostatic deposition method or any alternative painting method. This paint cover improves metal part protection and covers any joint spaces left between the metal sheet parts in order to assure a high IP protection of the CPV assembly system.

In an alternative embodiment of the invention, already surface treated or pre-painted external metal sheet parts 5, 6 and 8 are used in conjunction with watertight rivets for any external joints, thereby eliminating the need of any painting equipment in the assembly workshop.

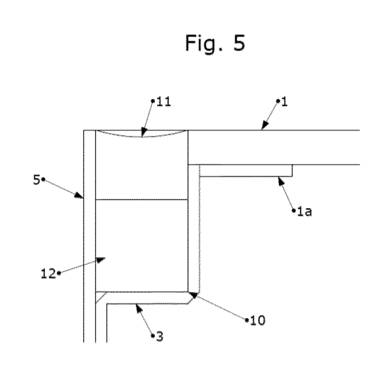

FIG. 5 is a cross-sectional view of the of the CPV assembly system. It can be observed that the components of the CPV assembly system are designed such that a channel 10 is formed between primary optics 1 and receiver panels 2 and frame 9.

In a preferred embodiment of the invention, channel 10 is filled with sealing silicone, sealing polyurethane or any other similar room temperature vulcanizing sealing material, making a continuous sealing joint 11. In another preferred embodiment a joint base 12 made from extruded PE foam or similar flexible material is inserted in the lower part of the channel before applying the sealing agent. This arrangement allows to reach the higher possible environmental protection for the assembled module, while posing no challenge to the mounting process of the module.

Those skilled in the art should appreciate that the foregoing discussion of one or more embodiments does not limit the present invention, nor do the accompanying figures. Rather, the present invention is limited only by the following claims:

1. A concentration photovoltaic CPV assembly system (200) comprising:
an upper primary optical section;
a lower photovoltaic receiving section;
a frame section comprising an internal section and an external section, wherein the frame section comprises premade holes for the assembly of the system; and
fixing means for assembling the upper, lower and frame sections together, wherein the fixing means comprises a first plurality of brackets mounted on the upper primary optical section enabling the assembly of the upper primary optical section to the upper part of the frame section, the brackets being accurately positioned based on primary optic reference points; and a second plurality of brackets mounted on the lower photovoltaic receiving section enabling its assembly to the lower part of the frame section; and
wherein the plurality of sections are substantially flat and the fixing means enable assembling the plurality of sections together permitting the sun light to be concentrated by the upper primary optical section in between the frame section onto the lower photovoltaic receiving section correctly.

2. The CPV assembly system of claim 1, wherein the upper primary optical section comprises at least one primary refractive optic, the lower photovoltaic receiving section comprises at least one CPV receiver, and the upper and lower sections are parallel with respect to each other.

3. The CPV assembly system of claim 2, wherein the height of the frame section is at least that of the focal length of the at least one primary refractive optic.

4. The CPV assembly system of claim 1, wherein the internal section comprises four internal walls.

5. The CPV assembly system of claim 1, wherein the external section comprises four external walls, and wherein the fixing means comprises watertight rivets for fastening the external walls.

6. The CPV assembly system of claim 1, wherein a channel is formed at the upper and lower portions of the frame section as the internal and external sections are assembled together thereby enabling a continuous watertight seal by filling with a sealing material such as sealing silicone and/or sealing polyurethane and/or other vulcanizing sealing material.

7. The CPV assembly system of claim 6, wherein a base is inserted in the lower part of the channel before applying the sealing material.

8. The CPV assembly system of claim 4, wherein the fixing means comprises an internal reinforcing means for assembling the internal walls together.

9. The CPV assembly system of claim 5, wherein the fixing means comprises an external reinforcing means for assembling the external walls together.

10. The CPV assembly system of claim 1, wherein the first and the second plurality of brackets are made of a stainless steel-like material and are glued using pressure sensitive and/or curing acrylic adhesive.

11. The CPV assembly system of claim 2, wherein the lower photovoltaic receiving section is painted at least on its backside, the frame section is painted with epoxy powder, the external walls are surface treated and/or pre-painted.

12. The CPV assembly system of claim 2, wherein the lower photovoltaic receiving section and the walls are computer numerically controlled, CNC, punched and/or laser cut.

13. A method for facilitating the assembly of a concentration photovoltaic CPV assembly system comprising a upper primary optical section, a lower photovoltaic receiving section, a frame section comprising an internal section and an external section, each section comprising premade holes for the assembly of the system, and fixing means for assembling the upper, lower and frame sections together, wherein the plurality of sections are substantially flat, the method comprising positioning a fixing means onto the upper primary optical section based on the primary optic reference points in such a manner enabling assembling the plurality of sections together permitting the sun light to be concentrated by the upper primary optical section in between the frame section onto the lower photovoltaic receiving section correctly, wherein the fixing means positioned onto the upper primary optical section comprises a first plurality of brackets enabling the assembly of the upper primary optical section to the upper part of the frame section, and a second plurality of brackets mounted on the lower photovoltaic receiving section enabling its assembly to the lower part of the frame section.
